(19) United States
(12) Patent Application Publication
(10) Pub. No.: US 2019/0272936 A1
(43) Pub. Date: Sep. 5, 2019

(54) FULLY EMBEDDED MAGNETIC-CORE IN CORE LAYER FOR CUSTOM INDUCTOR IN IC SUBSTRATE

(71) Applicant: Intel Corporation, Santa Clara, CA (US)

(72) Inventors: Chong ZHANG, Chandler, AZ (US); Cheng XU, Chandler, AZ (US); Ying WANG, Chandler, AZ (US); Junnan ZHAO, Gilbert, AZ (US); Meizi JIAO, Chandler, AZ (US); Yikang DENG, Chandler, AZ (US)

(21) Appl. No.: 15/911,549

(22) Filed: Mar. 5, 2018

(51) Int. Cl. H01F 27/24; G05F 1/10; H01L 49/02; H01F 41/02

(52) U.S. Cl. CPC H01F 27/24; H01F 41/0206; H01L 28/10; G05F 1/10

(57) ABSTRACT

Embodiments include inductors with embedded magnetic cores and methods of forming such inductors. Some embodiments may include an integrated circuit package that utilizes such inductors. For example, the integrated circuit package may include an integrated circuit die and a multi-phase voltage regulator electrically coupled to the integrated circuit die. In an embodiment, the multi-phase voltage regulator includes a substrate core and a plurality of inductors in the substrate core. In an embodiment, the inductors may include a conductive loop in and around the substrate core. In an embodiment, the conductive loops are electrically coupled to a voltage out line. Embodiments may also include a magnetic core surrounded by the conductive loops. The magnetic core is separated from surfaces of the conductive loops by the substrate core

### TECHNICAL FIELD

Embodiments of the present disclosure relate to power management solutions, and in particular to methods and apparatuses that include embedded magnetic cores for use in inductors.

### BACKGROUND

Efficient power management is crucial for many integrated circuit (IC) technologies, especially for high end server devices. Currently, voltage regulation in some ICs may be implemented with embedded voltage regulators. Such embedded voltage regulators often use air coil inductors (ACIs) formed by plating through hole walls with copper. However, ACIs may not provide the desired inductance. In order to increase the inductance, more ACIs may be formed in series. This increases the overall footprint of the voltage regulators. Additional solutions for increasing the inductances of ACIs have been proposed. For example, a magnetic core material may be positioned inside and around the coil.

However, the introduction of magnetic materials results in disruptions to currently used manufacturing processes. The magnetic materials leach and negatively affect chemistries used in the processing of IC substrates. For example, exposed magnetic materials may result in bath contamination during desmear, electroless copper plating, and subtractive etching processes.

### BRIEF DESCRIPTION OF THE DRAWINGS

FIG. 1A is a plan view of a multi-phase voltage regulator with single turn inductors formed around a plurality of embedded magnetic blocks, in accordance of an embodiment.

FIG. 1B is a cross-sectional illustration of the multi-phase voltage regulator in FIG. 1A along line B-B′, in accordance of an embodiment.

FIG. 2A is a plan view of a multi-phase voltage regulator with single turn inductors formed around a plurality of embedded magnetic pillars, in accordance with an embodiment.

FIG. 2B is a cross-sectional illustration of the multi-phase voltage regulator in FIG. 2A along line B-B′, in accordance with an embodiment.

FIG. 3A is a plan view of a multi-phase voltage regulator with single turn inductors formed around an embedded magnetic block, in accordance with an embodiment.

FIG. 3B is a cross-sectional illustration of the multi-phase voltage regulator in FIG. 3A along line B-B′, in accordance with an embodiment.

FIG. 4A is a plan view illustration of a multi-turn inductor formed around an embedded magnetic block, in accordance with an embodiment.

FIG. 4B is a cross-sectional illustration of the multi-turn inductor in FIG. 4A along line B-B′, in accordance with an embodiment.

FIG. 5 is a cross-sectional illustration of an inductor formed around an embedded magnetic block, in accordance with an embodiment.

FIG. 6A is a cross-sectional illustration of a substrate core, in accordance with an embodiment.

FIG. 6B is a cross-sectional illustration of an opening formed through the substrate core, in accordance with an embodiment.

FIG. 6C is a cross-sectional illustration of a magnetic core disposed in the opening through the substrate core, in accordance with an embodiment.

FIG. 6D is a cross-sectional illustration of a dielectric layer disposed over surfaces of magnetic core, in accordance with an embodiment.

FIG. 6E is a cross-sectional illustration of through-hole vias through the substrate core around the magnetic core, in accordance with an embodiment.

FIG. 6F is a cross-sectional illustration of plated through-hole vias around the magnetic core, in accordance with an embodiment.

FIG. 6G is a cross-sectional illustration of plugged through-hole vias around the magnetic core, in accordance with an embodiment.

FIG. 6H is a cross-sectional illustration of lid plated through-hole vias around the magnetic core, in accordance with an embodiment.

FIG. 7A is a cross-sectional illustration with a plurality of openings formed through a substrate core, in accordance with an embodiment.

FIG. 7B is a cross-sectional illustration of the substrate core with magnetic paste disposed in the plurality of openings, in accordance with an embodiment.

FIG. 7C is a cross-sectional illustration of a dielectric layer disposed over surfaces of the magnetic cores, in accordance with an embodiment.

FIG. 7D is a cross-sectional illustration of through-hole vias through the substrate core around the magnetic cores, in accordance with an embodiment.

FIG. 7E is a cross-sectional illustration of plated through-hole vias around the magnetic cores, in accordance with an embodiment.

FIG. 7F is a cross-sectional illustration of plugged through-hole vias around the magnetic cores with lids, in accordance with an embodiment.

FIG. 8 is a cross-sectional illustration of a packaged system that includes an inductor in the package substrate or the board substrate, in accordance with an embodiment.

FIG. 9 is a schematic of a computing device built in accordance with an embodiment.

### EMBODIMENTS OF THE PRESENT DISCLOSURE

Described herein are systems with fully embedded magnetic materials on IC substrates and methods of forming such systems. More particularly, embodiments include inductors with fully embedded magnetic cores and methods of forming such devices. In the following description, various aspects of the illustrative implementations will be described using terms commonly employed by those skilled in the art to convey the substance of their work to others skilled in the art. However, it will be apparent to those skilled in the art that the present invention may be practiced with only some of the described aspects. For purposes of explanation, specific numbers, materials and configurations are set forth in order to provide a thorough understanding of the illustrative implementations. However, it will be apparent to one skilled in the art that the present invention may be practiced without the specific details. In other instances, well-known features are omitted or simplified in order not to obscure the illustrative implementations.

Various operations will be described as multiple discrete operations, in turn, in a manner that is most helpful in understanding the present invention, however, the order of description should not be construed to imply that these operations are necessarily order dependent. In particular, these operations need not be performed in the order of presentation.

As noted above, the inclusion of magnetic materials in the manufacture of IC devices is currently problematic due to the leaching of magnetic materials (e.g., iron, alloys containing iron, and other ferromagnetic particles or elements) into processing baths. Accordingly, it is presently not feasible to integrate components, such as inductors, that benefit from the use of magnetic materials into IC substrates. However, embodiments described herein provide processing methods that allow for the integration of magnetic materials with currently available processing techniques. Particularly, embodiments include fully embedding magnetic materials so that the magnetic materials are not exposed to processing environments where the leaching of magnetic materials is detrimental. For example, embodiments include embedding the magnetic materials so that the magnetic materials are not exposed to processing environments that have chemistries that may be negatively altered by leached magnetic materials, such as electroless baths, and subtractive etching baths. Since the magnetic material is isolated from such environments, there is no need to redesign the chemistries of processing baths or provide dedicated processing baths to handle the magnetic materials. Furthermore, isolating the magnetic material allows for subsequent changes to the magnetic material to be made without needing to adjust the chemistries of processing environments. This allows for quicker design times and reduces the cost of development. In embodiments, the magnetic material always interfaces with an organic resin material instead of copper surfaces. This provides better reliability in terms of interface delamination and blistering.

In the particular embodiment of inductors that utilize fully embedded magnetic materials, it is to be appreciated that the inductors may have increased inductance relative to ACIs described above. As such, fewer turns are needed to provide a desired inductance relative to ACIs. Inductors with fully embedded magnetic cores, therefore, provide more efficient use of substrate area. Additionally, the plated through-hole pitch at the inductor area may be reduced compared to inductor structures that use a co-axial plated through-hole structure (i.e., forming a magnetic material around the plated through-hole in a co-axial structure). In co-axial plated through-hole structures, the pitch needs to be increased to accommodate for both the plated through-hole and the surrounding magnetic material. For example, the pitch needed to accommodate plated through-holes in co-axial arrangements may be 450 μm, and the pitch needed for plated through-holes described in embodiments herein may be 362.5 μm since the plated through-holes described herein may not be sheathed by the magnetic material.

In an embodiment, the plated through-holes in the inductor region may be the substantially similar (e.g., same pitch, geometry, and the like) as plated through-holes in other regions of the IC substrate. Additionally, the use of plated through-holes in the inductor region that are substantially similar to plated through-holes in the other regions of the substrate allow for a single set of drill bits to be used. This eliminates the cost of designing unique sets of drill bits specifically for the inductor region.

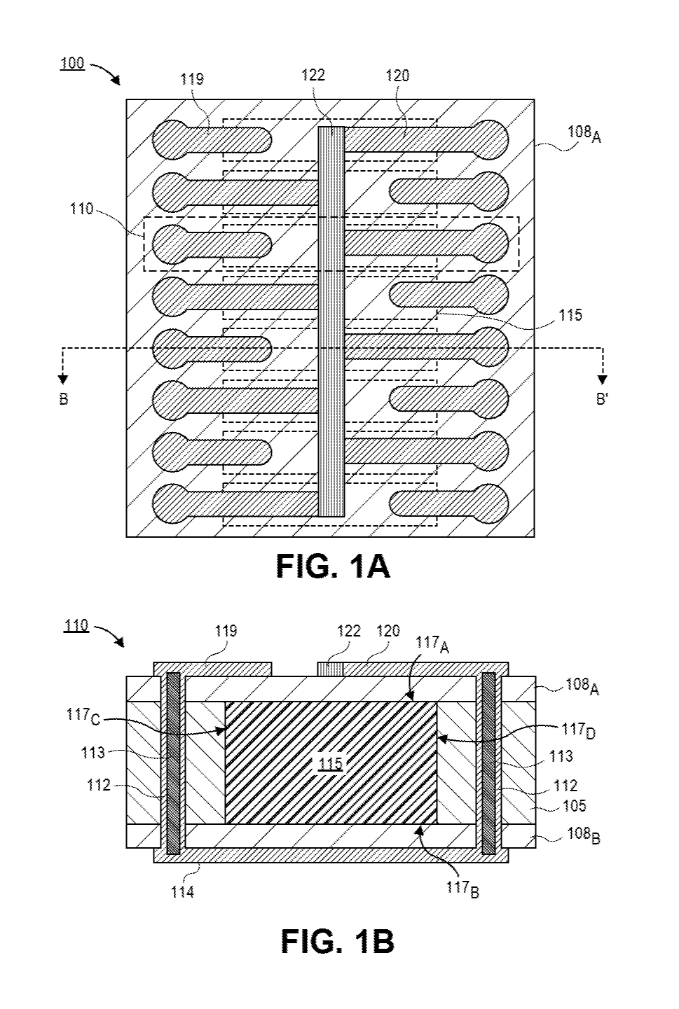

Referring now to FIGS. 1A and 1B, a plan view illustration and a cross-sectional illustration along line B-B′ of a multi-phase voltage regulator with a plurality of single turn inductors positioned around a magnetic core is shown, in accordance with an embodiment. In an embodiment, the multi-phase voltage regulator 100 may be disposed in and around a substrate core 105. In an embodiment, the substrate core 105 may be any suitable substrate on which build-up layers are formed. The substrate core 105 may be an organic material with or without reinforcement materials, such as glass fibers, particles, or the like.

In the illustrated embodiment, the multi-phase voltage regulator 100 includes eight single turn inductors 110. It is to be appreciated that any number of inductors 110 may be included in the multi-phase voltage regulator 100. Additionally, while single turn inductors 110 are illustrated in FIGS. 1A and 1B, it is to be appreciated that inductors 110 may include more than one turn.

As illustrated in FIG. 1B, the inductors 110 may include a pair of plated through-holes 112 that extend through the substrate core 105. In an embodiment, the plated through-holes 112 may be copper or any other suitable conductive material. The plated through-holes 112 may be filled with a dielectric material 113, such as an epoxy. First ends of the plated through-holes 112 may be electrically coupled to each other by a trace 114. The trace 114 may be a conductive material, such as copper. The inductors 110 may also include traces 119 and 120 that are electrically coupled to second ends of the plated through-holes 112. The traces 119 and 120 may be conductive material, such as copper. The traces 119 and 120 are portions of the conductive loop that form the single turn of the inductor 110. Trace 119 or 120 may also electrically couple the inductor 110 to a voltage-out (Vₒᵤₜ) line 122.

In an embodiment, the inductors 110 (including traces 119, 120, 114, and plated through-holes 112) are formed around a magnetic core 115. The magnetic core 115 may pass entirely through the substrate core 105. Surfaces 117_{A} and 117_{B} of the magnetic core 115 may be substantially coplanar with surfaces of the substrate core 105. As used herein, “substantially coplanar” may refer to surfaces that are within +/−2 μm of being coplanar with each other. In an embodiment, surfaces 117_{A} and 117_{B} may be in contact with dielectric layers 108_{A} and 108_{B}, respectively. Dielectric layers 108_{A} and 108_{B} cover the magnetic core 115 during processing operations and isolate the magnetic core 115 from processing operations that may negatively interact with the magnetic material (as will be described in greater detail below). In an embodiment, dielectric layers 108_{A} and 108_{B} may be a prepreg material. The dielectric layers 108_{A} and 108_{B} may be laminated over surfaces of the substrate core 105. In an embodiment, the plated through-holes may also pass through the dielectric layers 108_{A} and 108_{B}.

The magnetic core 115 may also have sidewall surfaces 117_{C} and 117_{B} that are in contact with the substrate core 105. In an embodiment, the sidewall surfaces 117_{C} and 117_{B} may be substantially vertical. As used herein, “substantially vertical” may refer to surfaces that are within +/−5° from 90°. Additional embodiments may include sidewall surfaces 117_{C} and 117_{B} that are tapered surfaces.

The magnetic core 115 may be any suitable magnetic material. In an embodiment, the magnetic core 115 may be a dielectric material that includes magnetic particles. In one embodiment, the magnetic particles may include iron, alloys including iron, or any other elements or alloys that have magnetic properties. In an embodiment, the magnetic core 115 may have a relative permeability greater than 5. In an embodiment, the magnetic core 115 may have a relative permeability greater than 10.

In FIG. 1A, the magnetic core 115 is illustrated with dashed lines to indicate it is formed below the dielectric layer 108_{A}. In an embodiment, a plurality of magnetic cores 115 are formed in the multi-phase voltage regulator 100. For example, each magnetic core 115 may be surrounded by a single inductor 110. However, it is to be appreciated that each magnetic core 115 may be surrounded by more than one inductor 110, in accordance with additional embodiments. Additional embodiments may also include a plurality of magnetic cores 115 being surrounded by a single inductor 110, as will be described in greater detail below.

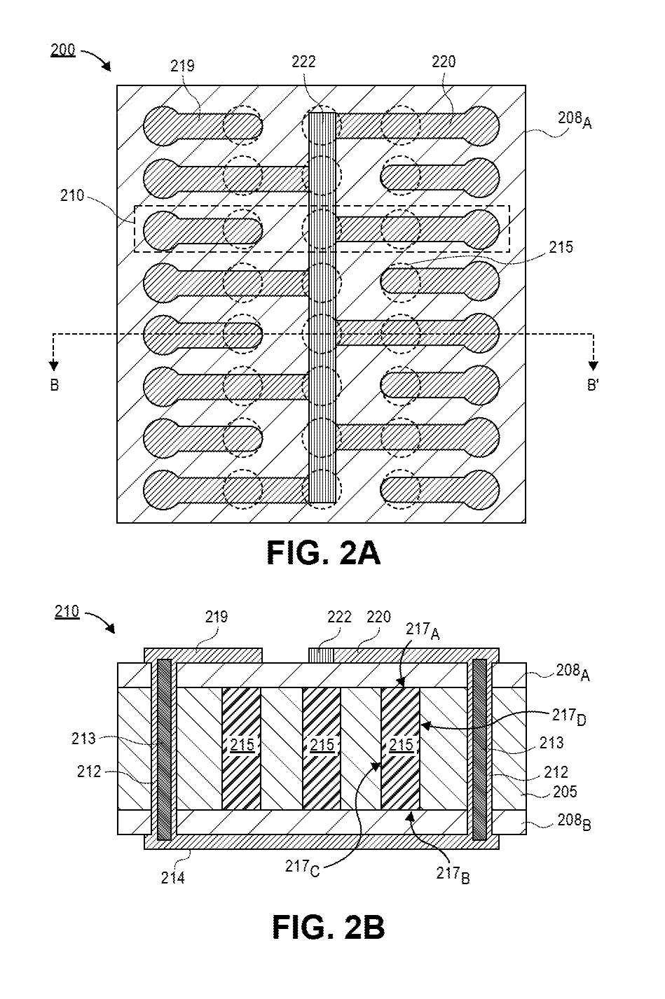

Referring now to FIGS. 2A and 2B, a plan view illustration and a cross-sectional illustration along lines B-B′ of a multi-phase voltage regulator is shown, in accordance with an embodiment. The multi-phase voltage regulator 200 in FIGS. 2A and 2B is substantially similar to the multi-phase voltage regulator 100 in FIGS. 1A and 1B with the exception that there are a plurality of magnetic cores 215 surrounded by each inductor 210. As illustrated, three magnetic cores 215 are surrounded by each inductor 210. However, embodiments also include two or more magnetic cores 215 being surrounded by each inductor 210.

The use of a plurality of magnetic cores 215 in each inductor 210 may allow for easier manufacturing. For example, the magnetic material used for the magnetic cores 215 may be a plugged into openings formed into the substrate core 205. Larger openings through the substrate core 205 may be relatively harder to form than smaller openings. As such, a plurality of smaller openings may be used to form a plurality of magnetic cores 215. In the illustrated embodiment, the magnetic cores 215 are cylindrical columns. However, embodiments are not limited to the shapes shown, and the magnetic cores 215 may have any desired cross-section.

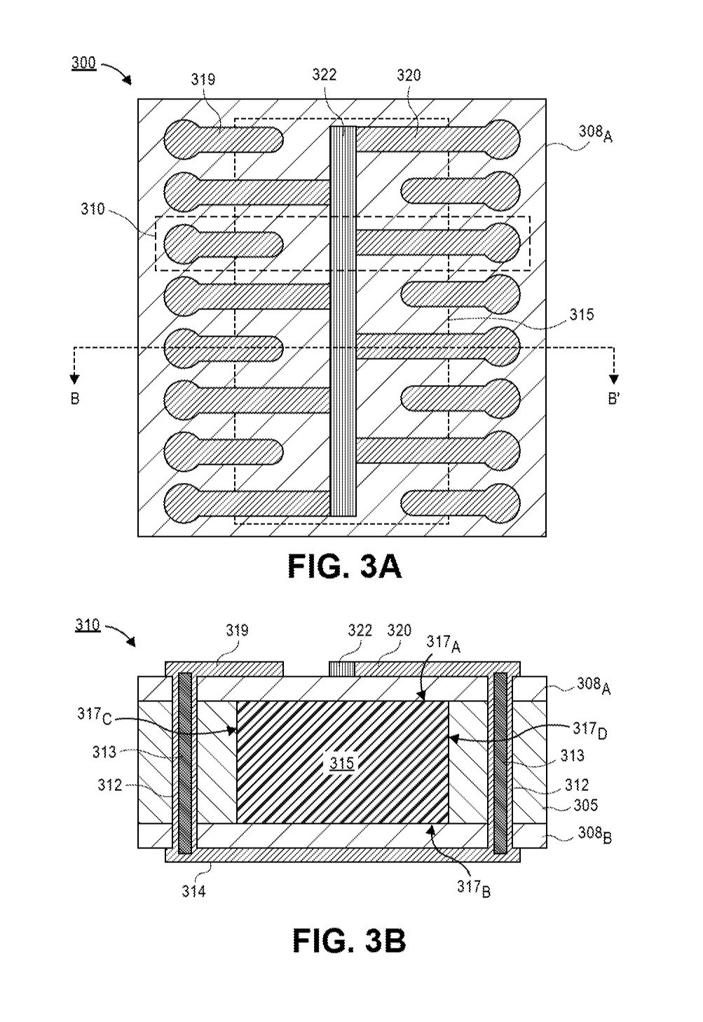

Referring now to FIGS. 3A and 3B, a plan view illustration and a cross-sectional illustration along lines B-B′ of a multi-phase voltage regulator is shown, in accordance with an embodiment. The multi-phase voltage regulator 300 in FIGS. 3A and 3B is substantially similar to the multi-phase voltage regulator 100 in FIGS. 1A and 1B with the exception that there is a single magnetic core 315 surrounded by a plurality of inductors 310. As illustrated, eight inductors 310 surround a single magnetic core 315. However, embodiments also include two or more inductors surrounding a single magnetic core 315. In the illustrated embodiment, the inductor 310 has a substantially rectangular shape. However, additional embodiments may include a magnetic core 315 with any suitable shape.

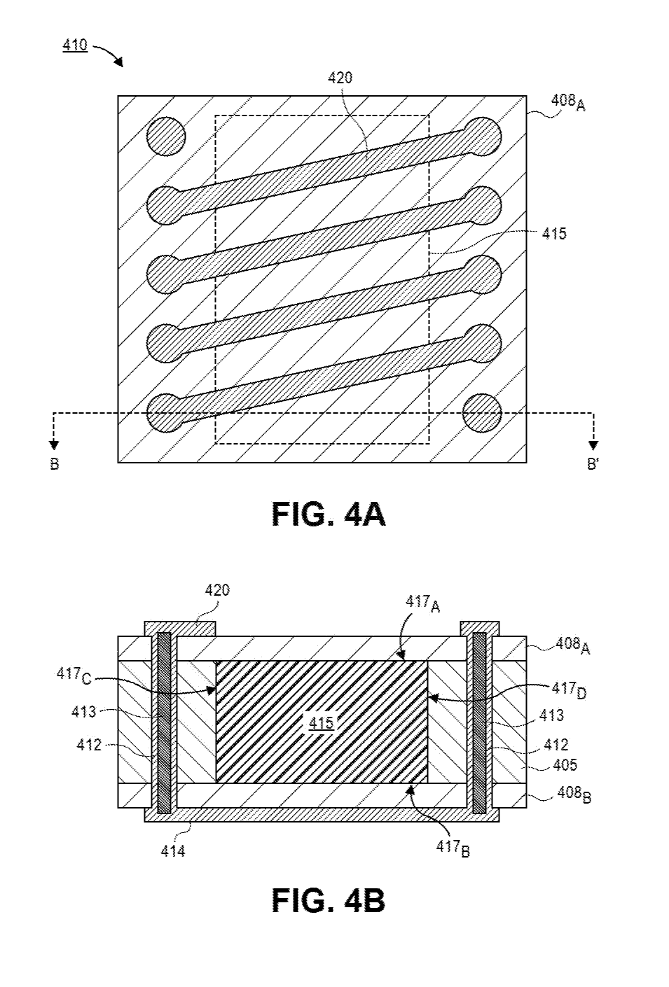

Referring now to FIGS. 4A and 4B, a plan view illustration and a cross-sectional view along line B-B′ of a multi-turn inductor 410 is shown, in accordance with an embodiment. In the illustrated embodiment, there are four turns shown, but it is to be appreciated that any number of turns may be used to provide a desired inductance. As shown in FIG. 4B, each turn of the inductor 410 has a substantially similar cross-section to the single turn inductor 310 illustrated in FIG. 3B. Additional embodiments may also include a plurality of magnetic cores 415 surrounded by the inductor 410, similar to the plurality of pillars in FIGS. 2A and 2B. Additional embodiments may also include a plurality of magnetic cores 415, each surrounded by one or more turns of the inductor 410, similar to the blocks of magnetic cores 115 in FIGS. 1A and 1B.

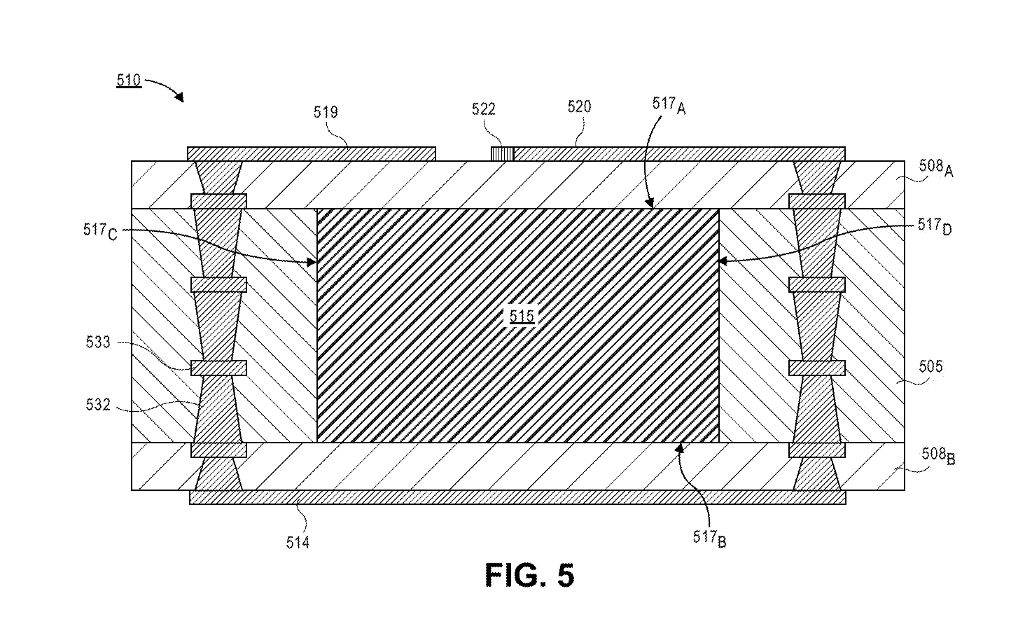

Referring now to FIG. 5, a cross-sectional illustration of an inductor with a magnetic core is shown, in accordance with a different embodiment. The inductor 510 illustrated in FIG. 5 may be substantially similar to the inductor illustrated in FIG. 1B, with the exception that the plated through-holes are replaced with patterned vias. In accordance with an embodiment, the patterned vias may include a via portion 532 and a pad portion 533. The vias 532 and pads 533 may be formed with lithographic patterning and laser drilling or the like, as is known in the art. In such an embodiment, the substrate core 505 may include a plurality of dielectric build-up layers (not shown for clarity). The vias 532 and pads 533 may be formed in the dielectric build-up layers of the substrate core 505 as the substrate core is formed using typical build-up layer fabrication processes. As such, embodiments are not limited to inductors formed with plated through-holes, and embodiments may include any through-via technology to form conductive portions of the inductor around the magnetic cores 515.

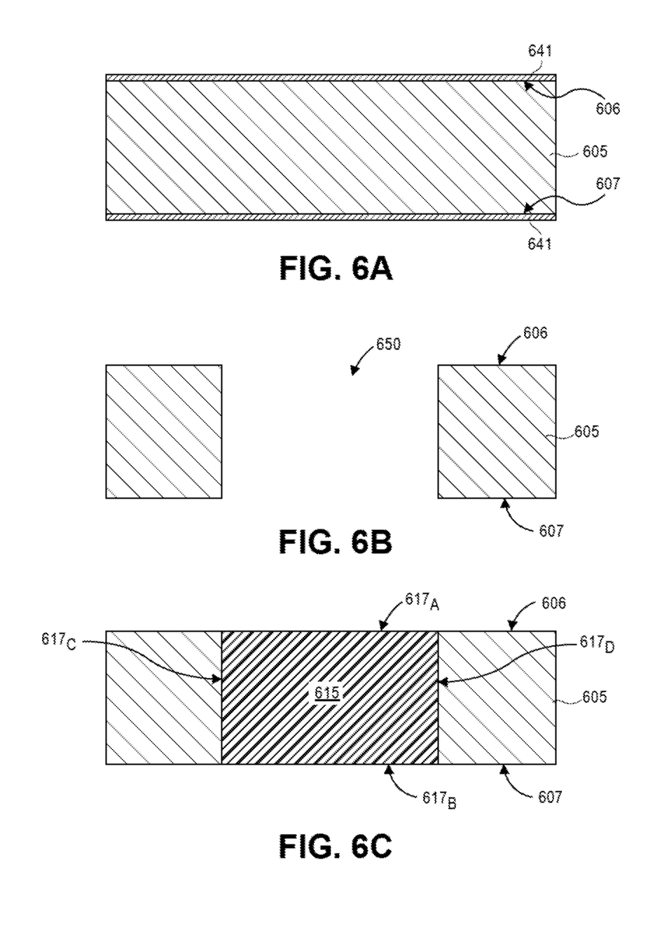

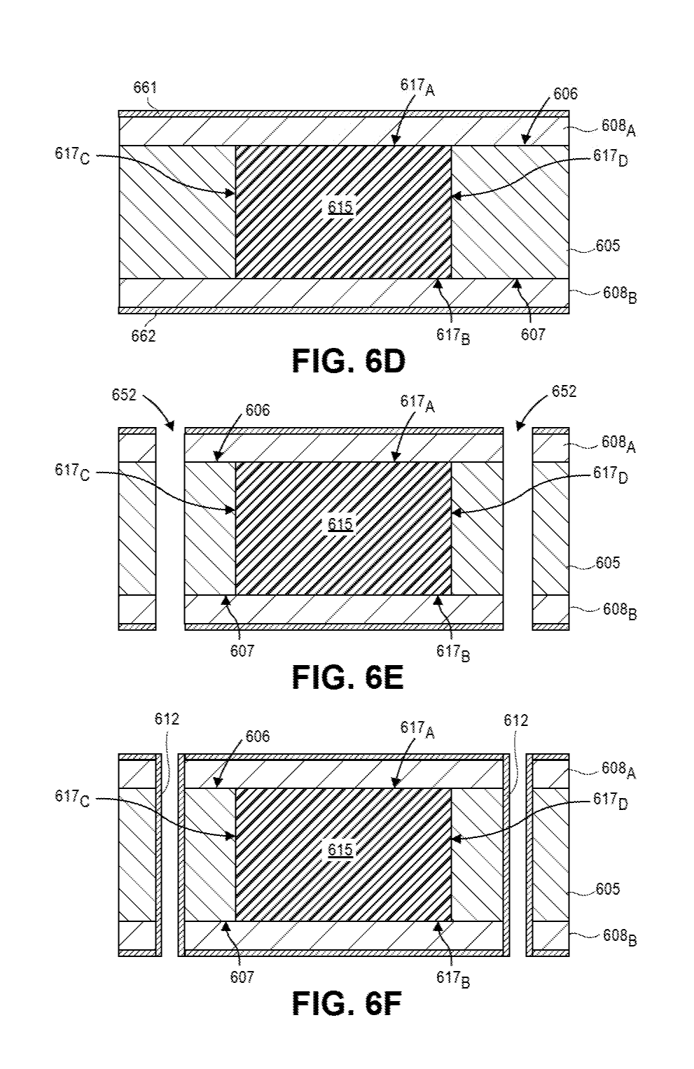

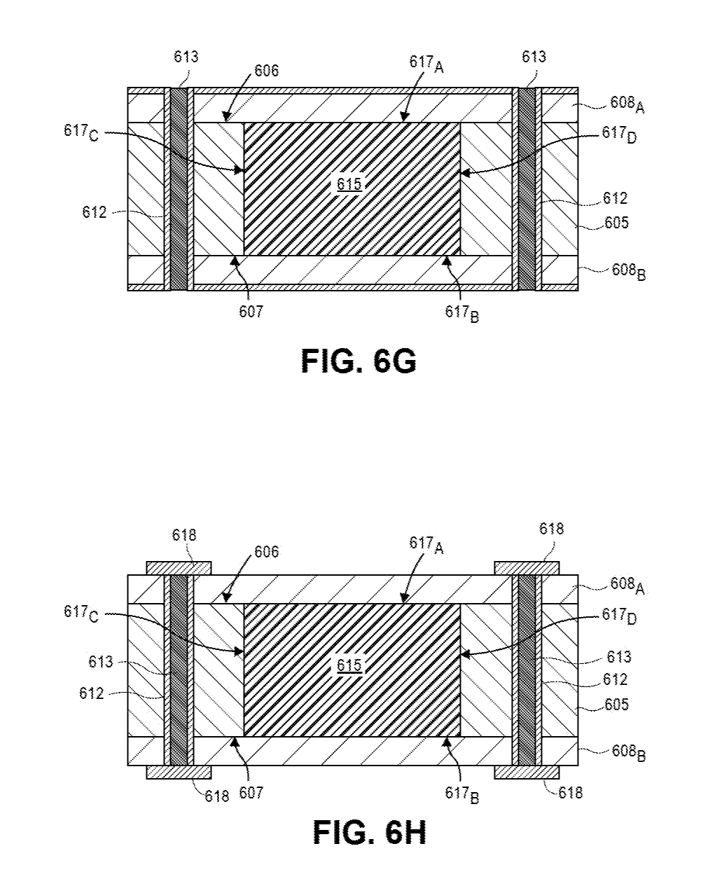

Referring now to FIGS. 6A-6H, a process flow for forming fully embedded magnetic materials that may be used for inductors is shown, in accordance with an embodiment. Embodiments described herein allow for the magnetic core to be formed and then isolated from processing environments throughout the remaining fabrication of an inductor. Accordingly, the magnetic material will not negatively affect the chemistries of processing baths, such as electroless plating baths, desmear baths, etching baths, or the like.

Referring now to FIG. 6A, a cross-sectional illustration of a substrate core 605 is shown, in accordance with an embodiment. In an embodiment, the substrate core 605 may be received with metal layers 641, such as copper, formed over a first surface 606 and second surface 607 of the substrate core 605.

Referring now to FIG. 6B, a cross-sectional illustration of the substrate core 605 is shown after an opening 650 is formed through the substrate core 605, in accordance with an embodiment. In an embodiment, the opening 650 may be formed through the substrate core 605 with any suitable process. For example, the opening 650 may be formed with a mechanical drilling process, a laser drilling process, a wet or dry etching process, or the like. Embodiments may also include an etching process that removes the metal layers 641 from the first surface 606 and the second surface 607 of the substrate core 605. In an embodiment, the opening 650 may be cleaned with a desmear process. In the illustrated embodiment, the sidewalls of the opening 650 are substantially vertical. However it is to be appreciated that embodiments may also include sidewalls of the opening 650 that are tapered or otherwise shaped, depending on the process used to form the opening 650.

Referring now to FIG. 6C, a cross-sectional illustration of the substrate core after a magnetic material is disposed in the opening is shown, in accordance with an embodiment. In an embodiment, the magnetic core 615 may be disposed in the opening 650 with any suitable process. In an embodiment, the magnetic core 615 may be plugged into the opening 650. After the magnetic material is plugged into the opening 650, a polishing process, a grinding process, or the like (e.g., chemical mechanical polishing (CMP)) may be used to remove any overburden of the magnetic material 650. The magnetic material used to form the magnetic core 615 may be cured.

In an embodiment, the magnetic core 615 may have a first surface 617_{A} that is substantially coplanar with a first surface 606 of the substrate core 605, and the magnetic core 615 may have a second surface 617_{B} that is substantially coplanar with a second surface 607 of the substrate core 605. Embodiments may also include a sidewall surfaces 617_{C} and 617_{D} that are in direct contact with the substrate core 605. The surfaces 617_{C} and 617_{D} may conform to the surfaces of the opening 650. As such, the profile of the surfaces 617_{C} and 617_{D} may match the profile of the opening 650 (i.e., vertical sidewalls, tapered sidewalls, etc.),

Referring now to FIG. 6D, a cross-sectional illustration of the substrate core 605 after dielectric layers 608_{A} and 608_{B} are disposed over the first surface 617_{A} and the second surface 617_{B} of the magnetic core is shown, in accordance with an embodiment. In an embodiment, the dielectric layers 608_{A} and 608_{B} may be laminated over the first surface 606 and the second surface 607 of the substrate core 605, respectively. The lamination may be implemented with a hot press. In additional embodiments, the dielectric layers 608_{A} and 608_{B} may be disposed over the substrate core with any other dry deposition process, such as printing, chemical vapor deposition (CVD), physical vapor deposition (PVD), plasma enhanced CVD (PECVD), or the like. In an embodiment, the dielectric layers 608_{A} and 608_{B} may be in direct contact with the first surface 617_{A} and the second surface 617_{B} of the magnetic core 615, respectively. Accordingly, embodiments include a magnetic core 615 that is fully embedded by the substrate core 605 and the first and second dielectric layers 608_{A} and 608_{B}. As such, subsequent processing operations may be implemented without exposing the magnetic core 615 to the processing environments.

In the illustrated embodiment, conductive layers 661, 662 are disposed over the first and second dielectric layers 608_{A} and 608_{B}. In some embodiments the conductive layers 661 and 662 may be formed on the dielectric layers 608_{A} and 608_{B} prior to the dielectric layers 608_{A} and 608_{B} being disposed over the substrate core 605. In other embodiments, one or both of the conductive layers 608_{A} and 608_{B} may be omitted.

Referring now to FIG. 6E, a cross-sectional illustration of the substrate core 605 after through-hole vias 652 are formed through the substrate core 605 is shown, in accordance with an embodiment. In an embodiment, the through-hole vias 652 may be formed with a mechanical drilling process. Additional embodiments may include forming the through-hole vias 652 with other processes, such as laser drilling, etching, or the like. In the illustrated embodiment, the through-hole vias 652 may have substantially vertical sidewalls. However, additional embodiments may include through-hole vias with any profile (e.g., tapered, or the like) depending on the process used to form the through-hole vias 652. In an embodiment, the through-hole vias 652 also are formed through the dielectric layers 608_{A} and 608_{B}, and the conductive layers 661 and 662. After the formation of the through-hole vias 652, embodiments may also include a desmear process. In such embodiments, magnetic core 615 is not exposed to the desmear environment since it is fully embedded.

Referring now to FIG. 6F, a cross-sectional illustration of the substrate core 605 after the through-hole vias are plated is shown, in accordance with an embodiment. In an embodiment, conductive material may be disposed along the sidewalls of the through-hole vias to form plated through-hole vias 612. The conductive material may be disposed on the sidewalls of the through-hole vias 612 with a plating process, such as an electroless plating process. In an embodiment, the conductive material may be copper or any other conductive material. In such embodiments, magnetic core 615 is not exposed to the electroless plating bath since it is fully embedded.

Referring now to FIG. 6G, a cross-sectional illustration of the substrate core 605 after a dielectric material is disposed into the openings 652 is shown, in accordance with an embodiment. In an embodiment, the dielectric material 613 may be disposed into the openings 652 with a plugging process, as is known in the art. In an embodiment, the dielectric material 613 may be an epoxy or any other suitable material. In an embodiment, the dielectric material 613 may be planarized with a top surface of the through-hole vias using a polishing or grinding process. In some embodiments, the dielectric material 613 may be cured with a curing process. In some embodiments, the dielectric material may be omitted and the through-hole vias 652 may be air filled.

Referring now to FIG. 6H, a cross-sectional illustration of the substrate core 605 after lids 618 are formed over the plated through-hole vias 612 is shown, in accordance with an embodiment. In an embodiment, the lids 618 are conductive lids and may be formed with any deposition process. For example, the lids 618 may be formed with an electroless plating process. After the plating, a subtractive etching process may be implemented to define the pattern of the lids 618 and remove the conductive layers 661 and 662. In some embodiments, the subtractive etching process may also be utilized to form conductive traces along surfaces of the dielectric layers 608_{A} and 608_{B} used to connect the plated through-hole vias 612 in order to form conductive loops that form one or more inductors, similar to those illustrated in FIGS. 1A-5. In such embodiments, magnetic core 615 is not exposed to the electroless plating environment or the wet subtractive etching environment since it is fully embedded.

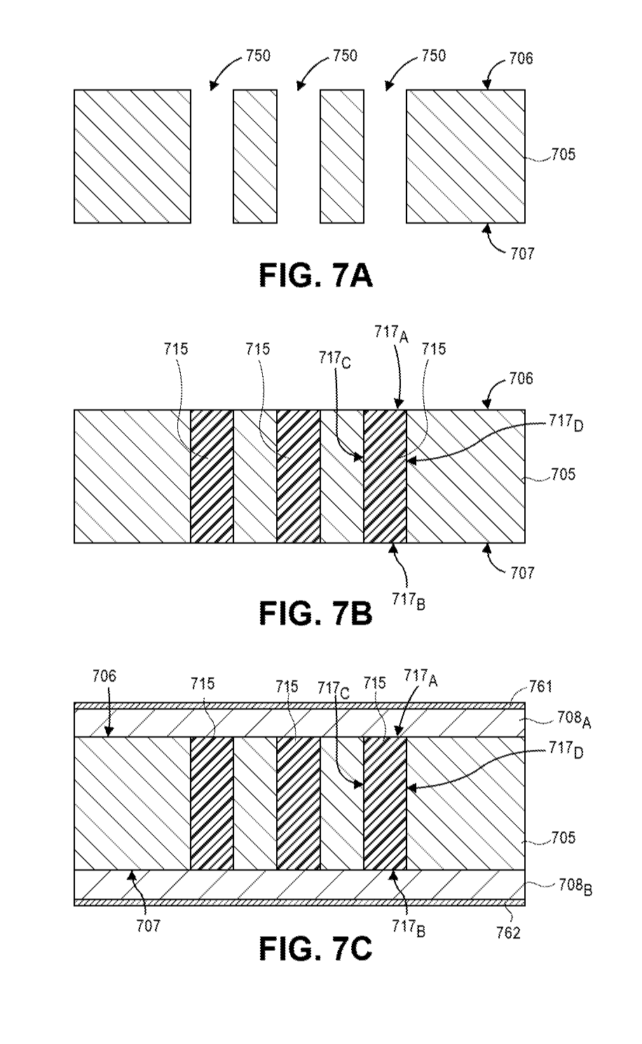

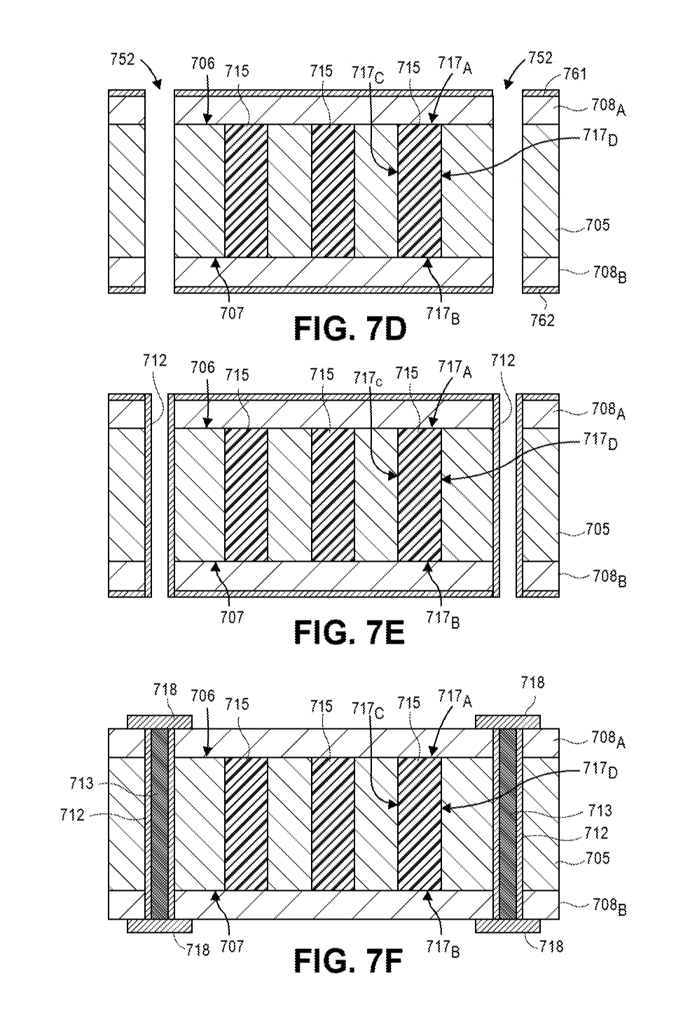

In other embodiments, there may be a plurality of magnetic cores formed within the core substrate. Such embodiments may be beneficial in order to improve the manufacturability of the embedded magnetic cores. Particularly, it may be easier to form smaller openings in the substrate core. A process flow for forming a plurality of fully embedded magnetic cores is shown in FIGS. 7A-7F.

Referring now to FIG. 7A, a cross-sectional illustration of a substrate core 705 after a plurality of openings 750 are formed through the substrate core is shown, in accordance with an embodiment. The substrate core 705 may be substantially similar to the substrate core 605 described above with respect to FIG. 6A. For example, the substrate core 750 may originally have metal layers over the first surface 706 and the second surface 707.

In the illustrated embodiment three openings 750 are formed through the substrate core 705. In other embodiments, any number of openings 750 may be formed through the substrate core 705. In an embodiment, the openings 750 may have any cross-section, as seen from the top similar to the view illustrated in FIG. 2B. For example, the cross-section may be circular, rectangular, square, or any other shape.

In an embodiment, the plurality of openings 750 may be formed through the substrate core 705 with any suitable process. For example, the openings 750 may be formed with a mechanical drilling process, a laser drilling process, a wet or dry etching process, or the like. In an embodiment, the openings 750 may be cleaned with a desmear process. In the illustrated embodiment, the vertical sidewalls of the openings 750 are substantially vertical. However, it is to be appreciated that embodiments may also include sidewalls of the openings 750 that are tapered or otherwise shaped, depending on the process used to form the openings 750.

Referring now to FIG. 7B, a cross-sectional illustration of the substrate core 705 after a magnetic material 715 is disposed in the openings 750 is shown, in accordance with an embodiment. In an embodiment, the magnetic cores 715 may be disposed in the openings 750 with any suitable process. In an embodiment, the magnetic cores 715 may be plugged into the openings 750. After the magnetic material is plugged into the openings 750, a polishing process, a grinding process, or the like (e.g., CMP) may be used to remove any overburden of the magnetic material 750. The magnetic material used to form the magnetic cores 715 may be cured.

In an embodiment, the magnetic cores 715 may have a first surface 717_{A} that is substantially coplanar with a first surface 706 of the substrate core 705, and the magnetic cores 715 may have a second surface 717_{B} that is substantially coplanar with a second surface 707 of the substrate core 705. Embodiments may also include sidewall surfaces 717_{C} and 717_{D} that are in direct contact with the substrate core 705. The surfaces 717_{C} and 717_{D} may conform to the surfaces of the opening 750. As such, the profile of the surfaces 717_{C} and 717_{D} may match the profile of the opening 750 (i.e., vertical sidewalls, tapered sidewalls, etc.),

Referring now to FIG. 7C, a cross-sectional illustration of the substrate core 705 after dielectric layers 708_{A} and 708_{B} are disposed over the first surface 717_{A} and the second surface 717_{B} of the magnetic cores is shown, in accordance with an embodiment. In an embodiment, the dielectric layers 708_{A} and 708_{B} may be laminated over the first surface 706 and the second surface 707 of the substrate core 705, respectively. The lamination may be implemented with a hot press. In additional embodiments, the dielectric layers 708_{A} and 708_{B} may be disposed over the substrate core with any other dry deposition process, such as printing, CVD, PVD, PECVD, or the like. In an embodiment, the dielectric layers 708_{A} and 708_{B} may be in direct contact with the first surface 717_{A} and the second surface 717_{B} of the magnetic cores 715, respectively. Accordingly, embodiments include magnetic cores 715 that are fully embedded by the substrate core 705 and the first and second dielectric layers 708_{A} and 708_{B}. As such, subsequent processing operations may be implemented without exposing the magnetic cores 715 to the processing environments.

In the illustrated embodiment, conductive layers 761, 762 are disposed over the first and second dielectric layers 708_{A} and 708_{B}. In some embodiments, the conductive layers 761 and 762 may be formed on the dielectric layers 708_{A} and 708_{B} prior to the dielectric layers 708_{A} and 708_{B} being disposed over the substrate core 705. In other embodiments, one or both of the conductive layers 708_{A} and 708_{B} may be omitted.

Referring now to FIG. 7D, a cross-sectional illustration of the substrate core 705 after through-hole vias 752 are formed through the substrate core 705 is shown, in accordance with an embodiment. In an embodiment, the through-hole vias 752 may be formed with a mechanical drilling process. Additional embodiments may include forming the through-hole vias 752 with other processes, such as laser drilling, etching, or the like. In the illustrated embodiment, the through-hole vias 752 may have substantially vertical sidewalls. However, additional embodiments may include through-hole vias with any profile (e.g., tapered, or the like) depending on the process used to form the through-hole vias 752. In an embodiment, the through-hole vias 752 also are formed through the dielectric layers 708_{A} and 708_{B}, and the conductive layers 761 and 762. After the formation of the through-hole vias 752, embodiments may also include a desmear process. In such embodiments, magnetic cores 715 are not exposed to the desmear environment since they are fully embedded.

Referring now to FIG. 7E, a cross-sectional illustration of the substrate core 705 after the through-hole vias are plated is shown, in accordance with an embodiment. In an embodiment, conductive material may be disposed along the sidewalls of the through-hole vias to form plated through-hole vias 712. The conductive material may be disposed on the sidewalls of the through-hole vias 712 with a plating process, such as an electroless plating process. In an embodiment, the conductive material may be copper or any other conductive material. In such embodiments, magnetic cores 715 are not exposed to the electroless plating bath since they are fully embedded.

Referring now to FIG. 7F, a cross-sectional illustration of the substrate core 705 after a dielectric material is disposed into the openings 752 and lids 718 are formed over the plated through-hole vias 712 is shown, in accordance with an embodiment. In an embodiment, the dielectric material 713 may be disposed into the openings 752 with a plugging process, as is known in the art. In an embodiment, the dielectric material 713 may be an epoxy or any other suitable material. In an embodiment, the dielectric material 713 may be planarized with a top surface of the through-hole vias using a polishing or grinding process. In some embodiments, the dielectric material 713 may be cured with a curing process. In some embodiments, the dielectric material may be omitted and the through-hole vias 752 may be air filled.

In an embodiment, the lids 718 are conductive lids and may be formed with any deposition process. For example, the lids 718 may be formed with an electroless plating process. After the plating, a subtractive etching process may be implemented to define the pattern of the lids 718 and remove the conductive layers 761 and 762. In some embodiments, the subtractive etching process may also be utilized to form conductive traces along surfaces of the dielectric layers 708_{A} and 708_{B} used to connect the plated through-hole vias 712 in order to form conductive loops that form one or more inductors, similar to those illustrated in FIGS. 1A-5. In such embodiments, magnetic cores 715 are not exposed to the electroless plating environment or the wet subtractive etching environment since they are fully embedded.

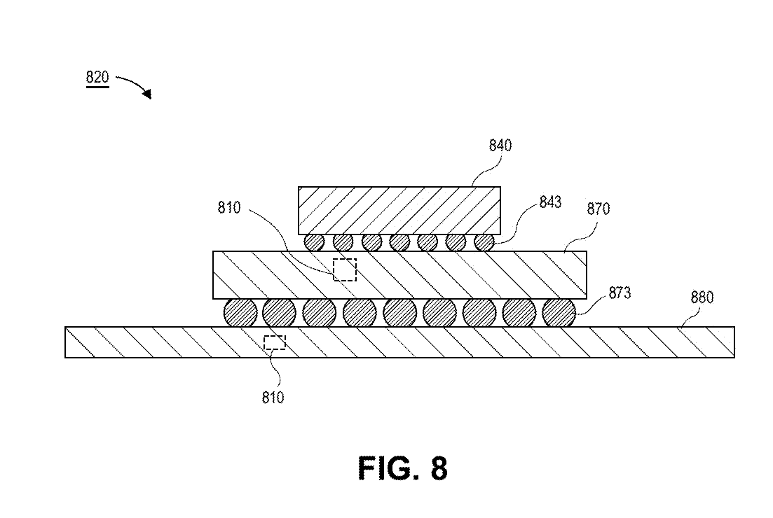

Referring now to FIG. 8, a cross-sectional illustration of a packaged system 820 is shown, in accordance with an embodiment. In an embodiment, the packaged system 820 may include a die 840 electrically coupled to a package substrate 870 with solder bumps 843. In additional embodiments, the die 840 may be electrically coupled to the package substrate 870 with any suitable interconnect architecture, such as wire bonding or the like. The package substrate 870 may be electrically coupled to a board, such as a printed circuit board (PCB) with solder bumps 873 or any other suitable interconnect architecture, such as wire bonding or the like.

In an embodiment, an inductor 810 similar to embodiments described above may be integrated into the package substrate 870 or the board 880, or the package substrate 870 and the board 880. Embodiments include any number of inductors 810 formed into the package substrate 870 and the board 880. For example, a plurality of inductors 810 may be integrated into the circuitry of the package substrate 870 or the board 880, or the package substrate 870 and the board 880 for power management, filtering, or any other desired use.

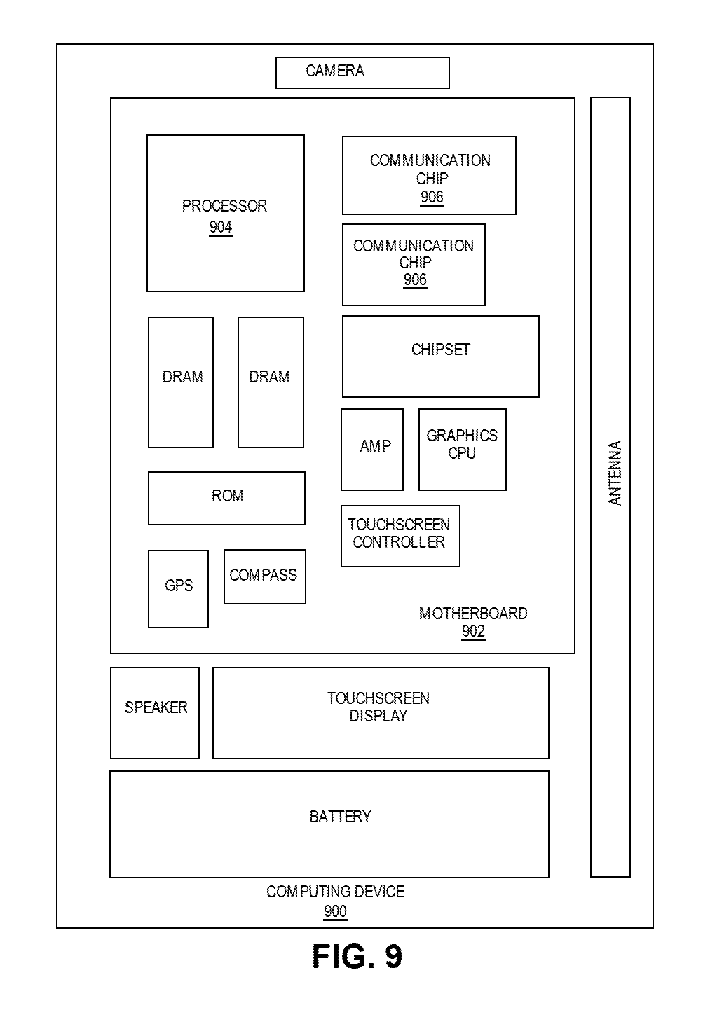

FIG. 9 illustrates a computing device 900 in accordance with one implementation of the invention. The computing device 900 houses a board 902. The board 902 may include a number of components, including but not limited to a processor 904 and at least one communication chip 906. The processor 904 is physically and electrically coupled to the board 902. In some implementations the at least one communication chip 906 is also physically and electrically coupled to the board 902. In further implementations, the communication chip 906 is part of the processor 904.

These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 906 enables wireless communications for the transfer of data to and from the computing device 900. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 906 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 900 may include a plurality of communication chips 906. For instance, a first communication chip 906 may be dedicated to shorter range wireless communications such as Wi-Fi and Bluetooth and a second communication chip 906 may be dedicated to longer range wireless communications such as GPS, EDGE, GPRS, CDMA, WiMAX, LTE, Ev-DO, and others.

The processor 904 of the computing device 900 includes an integrated circuit die packaged within the processor 904. In some implementations of the invention, the integrated circuit die of the processor may include inductors with fully embedded magnetic cores in accordance with embodiments described herein. The term “processor” may refer to any device or portion of a device that processes electronic data from registers and/or memory to transform that electronic data into other electronic data that may be stored in registers and/or memory.

The communication chip 906 also includes an integrated circuit die packaged within the communication chip 906. In accordance with another implementation of the invention, the integrated circuit die of the communication chip includes one or more devices, such as devices that may include inductors with fully embedded magnetic cores in accordance with embodiments described herein.

The above description of illustrated implementations of the invention, including what is described in the Abstract, is not intended to be exhaustive or to limit the invention to the precise forms disclosed. While specific implementations of, and examples for, the invention are described herein for illustrative purposes, various equivalent modifications are possible within the scope of the invention, as those skilled in the relevant art will recognize.

These modifications may be made to the invention in light of the above detailed description. The terms used in the following claims should not be construed to limit the invention to the specific implementations disclosed in the specification and the claims. Rather, the scope of the invention is to be determined entirely by the following claims, which are to be construed in accordance with established doctrines of claim interpretation.

Example 1 may include an inductor, comprising: a substrate core; a magnetic core embedded within the substrate core; a first dielectric layer over a first surface of the magnetic core; a second dielectric layer over a second surface of the magnetic core; and a conductive loop around the magnetic core, wherein the magnetic core is separated from the conductive loop by the substrate core, the first dielectric layer, and the second dielectric layer.

Example 2 may include the inductor of Example 1, wherein a plurality of conductive loops are formed around the magnetic core.

Example 3 may include the inductor of Example 1 or Example 2, wherein a plurality of magnetic cores are surrounded by the conductive loop.

Example 4 may include the inductor of Examples 1-3, wherein the conductive loop comprises plated through-hole vias disposed through the substrate core.

Example 5 may include the inductor of Examples 1-4, wherein a first plated through-hole vias is disposed adjacent to a first sidewall of the magnetic core and a second plated through-hole via is disposed adjacent to a second sidewall of the magnetic core.

Example 6 may include the inductor of Examples 1-5, wherein the conductive layers of the first and second through-hole vias are separated from the magnetic core by portions of the substrate core.

Example 7 may include the inductor of Examples 1-6, wherein the conductive loop further comprises a first trace over a first surface of the substrate core and second trace over a second surface of the substrate core.

Example 8 may include the inductor of Examples 1-7, wherein the first trace is separated from the magnetic core by the first dielectric layer and the second trace is separated from the magnetic core by the second dielectric layer.

Example 9 may include the inductor of Examples 1-8, wherein the through-hole vias pass through the first dielectric layer and the second dielectric layer.

Example 10 may include a multi-phase voltage regulator, comprising: a substrate core; a plurality of inductors, wherein the inductors comprise a conductive loop in and around the substrate core, wherein the conductive loops are electrically coupled to a voltage out line; and a magnetic core surrounded by the conductive loops, wherein the magnetic core is separated from surfaces of the conductive loops by the substrate core.

Example 11 may include the multi-phase voltage regulator of Example 10, wherein the magnetic core is separated from the surface of the conductive loops by the substrate core and by a first dielectric layer formed over a first surface of the magnetic core and a second dielectric layer formed over the second surface of the magnetic core.

Example 12 may include the multi-phase voltage regulator of Example 10 or Example 11, wherein the conductive loops surround different magnetic cores.

Example 13 may include the multi-phase voltage regulator of Examples 10-12, wherein conductive loops surround a plurality of magnetic cores.

Example 14 may include the multi-phase voltage regulator of Examples 10-13, wherein a single magnetic core is surrounded by the plurality of conductive loops.

Example 15 may include the multi-phase voltage regulator of Examples 10-14, wherein one or more of the plurality of inductors includes a conductive loop with two or more turns.

Example 16 may include a method for forming an inductor with a fully embedded magnetic core, comprising: forming an opening through a substrate core; filling the opening with a magnetic material to form a magnetic core; disposing a first dielectric layer over a first surface of the magnetic core; disposing a second dielectric layer over a second surface of the magnetic core; and forming through hole vias through the substrate core, wherein surfaces of the magnetic core are separated from the vias by the substrate core.

Example 17 may include the Example of claim 16, further comprising: forming a plurality of openings through the substrate core; and filling the plurality of openings with a magnetic material to form a plurality of magnetic cores.

Example 18 may include the method of Example 16 or Example 17, wherein the magnetic material is a plugging material that is plugged into the opening and cured.

Example 19 may include the method Examples 16-18, wherein the first dielectric layer and the second dielectric layer are laminated over the first and second surfaces of the magnetic core.

Example 20 may include the method of Examples 16-19, wherein the vias are plated through-hole vias.

Example 21 may include the method of Examples 16-20, wherein the vias are lithographically or laser drill defined vias.

Example 22 may include the method of Examples 16-21, wherein the magnetic core is fully embedded by the substrate core, the first dielectric layer, and the second dielectric layer prior to forming the vias.

Example 23 may include an integrated circuit package comprising: an integrated circuit die; a multi-phase voltage regulator electrically coupled to the integrated circuit die, wherein the multi-phase voltage regulator comprises: a substrate core; a plurality of inductors, wherein the inductors comprise a conductive loop in and around the substrate core, wherein the conductive loops are electrically coupled to a voltage out line; and a magnetic core surrounded by the conductive loops, wherein the magnetic core is separated from surfaces of the conductive loops by the substrate core.

Example 24 may include the integrated circuit package of Example 23, further comprising a plurality of magnetic cores within the conductive loops.

Example 25 may include the integrated circuit package of Example 23 or 24, further comprising: a first dielectric layer over a first surface of the magnetic core; and a second dielectric layer over a second surface of the magnetic core.

What is claimed is:

1. An inductor, comprising:
a substrate core;
a magnetic core embedded within the substrate core;
a first dielectric layer over a first surface of the magnetic core;
a second dielectric layer over a second surface of the magnetic core; and
a conductive loop around the magnetic core, wherein the magnetic core is separated from the conductive loop by the substrate core, the first dielectric layer, and the second dielectric layer.

2. The inductor of claim 1, wherein a plurality of conductive loops are formed around the magnetic core.

3. The inductor of claim 1, wherein a plurality of magnetic cores are surrounded by the conductive loop.

4. The inductor of claim 1, wherein the conductive loop comprises plated through-hole vias disposed through the substrate core.

5. The inductor of claim 4, wherein a first plated through-hole vias is disposed adjacent to a first sidewall of the magnetic core and a second plated through-hole via is disposed adjacent to a second sidewall of the magnetic core.

6. The inductor of claim 5, wherein the conductive layers of the first and second through-hole vias are separated from the magnetic core by portions of the substrate core.

7. The inductor of claim 4, wherein the conductive loop further comprises a first trace over a first surface of the substrate core and second trace over a second surface of the substrate core.

8. The inductor of claim 7, wherein the first trace is separated from the magnetic core by the first dielectric layer and the second trace is separated from the magnetic core by the second dielectric layer.

9. The inductor of claim 4, wherein the through-hole vias pass through the first dielectric layer and the second dielectric layer.

10. A multi-phase voltage regulator, comprising:
a substrate core;
a plurality of inductors, wherein the inductors comprise a conductive loop in and around the substrate core, wherein the conductive loops are electrically coupled to a voltage out line; and
a magnetic core surrounded by the conductive loops, wherein the magnetic core is separated from surfaces of the conductive loops by the substrate core.

11. The multi-phase voltage regulator of claim 10, wherein the magnetic core is separated from the surface of the conductive loops by the substrate core and by a first dielectric layer formed over a first surface of the magnetic core and a second dielectric layer formed over the second surface of the magnetic core.

12. The multi-phase voltage regulator of claim 10, wherein the conductive loops surround different magnetic cores.

13. The multi-phase voltage regulator of claim 10, wherein conductive loops surround a plurality of magnetic cores.

14. The multi-phase voltage regulator of claim 10, wherein a single magnetic core is surrounded by the plurality of conductive loops.

15. The multi-phase voltage regulator of claim 10, wherein one or more of the plurality of inductors includes a conductive loop with two or more turns.

16. A method for forming an inductor with a fully embedded magnetic core, comprising:
forming an opening through a substrate core;
filling the opening with a magnetic material to form a magnetic core;
disposing a first dielectric layer over a first surface of the magnetic core;
disposing a second dielectric layer over a second surface of the magnetic core; and
forming through hole vias through the substrate core, wherein surfaces of the magnetic core are separated from the vias by the substrate core.

17. The method of claim 16, further comprising:
forming a plurality of openings through the substrate core; and
filling the plurality of openings with a magnetic material to form a plurality of magnetic cores.

18. The method of claim 16, wherein the magnetic material is a plugging material that is plugged into the opening and cured.

19. The method of claim 16, wherein the first dielectric layer and the second dielectric layer are laminated over the first and second surfaces of the magnetic core.

20. The method of claim 16, wherein the vias are plated through-hole vias.

21. The method of claim 16, wherein the vias are lithographically or laser drill defined vias.

22. The method of claim 16, wherein the magnetic core is fully embedded by the substrate core, the first dielectric layer, and the second dielectric layer prior to forming the vias.

23. An integrated circuit package comprising:
an integrated circuit die;
a multi-phase voltage regulator electrically coupled to the integrated circuit die, wherein the multi-phase voltage regulator comprises:
a substrate core;
a plurality of inductors, wherein the inductors comprise a conductive loop in and around the substrate core, wherein the conductive loops are electrically coupled to a voltage out line; and
a magnetic core surrounded by the conductive loops, wherein the magnetic core is separated from surfaces of the conductive loops by the substrate core.

24. The integrated circuit package of claim 23, further comprising a plurality of magnetic cores within the conductive loops.

25. The integrated circuit package of claim 23, further comprising:
a first dielectric layer over a first surface of the magnetic core; and
a second dielectric layer over a second surface of the magnetic core.
